(19) United States
(12) Patent Application Publication
(10) Pub. No.: US 2019/0296011 A1
(43) Pub. Date: Sep. 26, 2019

(54) MEANS FOR REDUCING FINFET PARASITIC RESISTANCE

(71) Applicants: SHANGHAI IC R&D CENTER CO., LTD., Shanghai (CN); CHENGDU IMAGE DESIGN TECHNOLOGY CO., LTD., Chengdu (CN)

(72) Inventors: Ao GUO, Shanghai (CN); Linlin LIU, Shanghai (CN)

(21) Appl. No.: 16/465,575

(22) PCT Filed: Jun. 6, 2017
(86) PCT No.: PCT/CN2017/087281

§ 371 Date: May 31, 2019

(30) Foreign Application Priority Data
Dec. 27, 2016 (CN) 201611230454.3

(51) Int. Cl. H01L 27/088; H01L 29/78; H01L 29/16; H01L 29/06; H01L 29/66; H01L 21/8234; C01B 32/162

(52) U.S. Cl. CPC H01L 27/0886; H01L 29/785; H01L 29/16; H01L 29/0649; H01L 2029/7858; H01L 21/823431; H01L 21/823475; H01L 21/823437; C01B 32/162; H01L 29/66795

(57) ABSTRACT

A device structure for reducing FinFET parasitic resistance and a manufacturing method thereof. The method comprises preparing a FinFET device like conventional FinFET structure, including preparing a FinFET silicon fin, forming a gate stack consisting of a gate electrode and a gate dielectric layer, and defining a source-drain region of the FinFET device; wherein the gate stack, which formed by the gate electrode and the gate dielectric layer in the FinFET device, wraps the FinFET silicon fin from the two sides and the surface respectively, to form a three-dimensional channel of the MOSFET; preparing a catalyst layer in the source-drain region; growing a carbon nanotube, to form a strip-shaped contact hole layer M0; wherein, the lower end of the strip-shaped contact hole layer M0 covers and connects the source-drain region of the FinFET device; the material of the strip-shaped contact hole layer M0 is a single-wall carbon nanotube or multi-wall carbon nanotube; and achieving the source-drain region connecting-out and the back-end process for preparation of the FinFET device, wherein the upper end of the strip-shaped contact hole layer M0 is connected to the metal layer M1.

### CROSS-REFERENCE TO RELATED APPLICATION

This application claims priority of International Patent Application Serial No. PCT/CN2017/087281, filed Jun. 6, 2017, which is related to and claims priority of Chinese patent application Serial No. 201611230454.3, filed Dec. 27, 2016. The entirety of each of the above-mentioned patent applications is hereby incorporated herein by reference and made a part of this specification.

### TECHNICAL FIELD

The present disclosure relates to technical field of integrated circuit manufacturing, in particular to a method for reducing Fin Field-Effect Transistor (FinFET) parasitic resistance in a semiconductor product manufacturing process.

### BACKGROUND

With the technology node of semiconductor process shrinks continuously, the processes of the traditional planar Metal-Oxide Semiconductor Field-Effect Transistor (MOSFET) are presented more and more technical challenges.

As a new type of three-dimensional device structure, the FinFET can greatly improve the device characteristics of the MOSFET, which can include suppression of short channel effect (SCE), reduction of device leakage, enhancement of drive current, improvement of sub-threshold characteristics, and so on.

The world's leading semiconductor foundries have already mass produced the FinFET in 16/14 nm process nodes at present. Referring to FIG. 1, FIG. 1 shows a typical schematic diagram of the FinFET device structure in the prior art. Wherein a gate stack composed of a gate electrode and a gate dielectric layer wraps the Silicon Fin (Si Fin) from the side and the surface respectively to form a three-dimensional channel of the MOSFET. Because the width of the Si Fin is very small, the source-drain electrode is usually connected out through the strip-shaped contact hole layer M0, and further connected to the metal layer M1 through the contact hole layer V0, so that the correlation process of the traditional back-end process is completed.

As can be seen from FIG. 1, although the FINFET technology facilitates the further reduction of the MOS device size, the parasitic resistance and the parasitic capacitance caused by the three-dimensional device structure are more serious than those caused by the planar MOS device, especially with the size of the FinFET device is further narrowed to 7 nm technology generation, the parasitic resistance and the parasitic capacitance of the FinFET device will become a decisive factor affecting the performance of the FinFET device, so that a great challenge is brought to further improvement of the performance of the FinFET device.

Referring to FIG. 2, FIG. 2 shows a typical parasitic resistance schematic diagram of a FinFET device in the prior art. As shown in the figure, the parasitic resistance mainly comprises a parasitic resistance R_SD of the source-drain region, a resistance R_extension of the Si Fin extension region between the source-drain and the channel, and a contact resistance R_contact when the source-drain region is connected out through the source-drain metal layer M0.

Please refer to FIG. 3, FIG. 3 shows the simulation results of parasitic resistance of the FinFET device at each process node. As shown in the figure, with the FinFET device size decreasing, the parasitic resistance R_SD and the resistance R_extension have little change, but the contact resistance R_contact increases obviously.

Therefore, reducing the contact resistance R_contact generated when the strip-shaped contact hole layer M0 is connected out, has become the main direction of improving the parasitic resistance of the FinFET device and device performance, and it is also a key problem to be solved for further scaling down the size along the FinFET technology route.

In the current mainstream FinFET technology, the strip-shaped contact hole layer M0 is usually filled with metal tungsten, those skilled in the art are trying to reduce the contact resistance R_contact between the strip-shaped contact hole layer M0 and the source-drain region through various ways, so as to the more advanced techniques be applied to the FinFET process. For example, the techniques mainly include regulating the schottky barrier for metal-semiconductor contact by interface engineering, performing silicide processing on the source-drain region, and filling the strip-shaped contact hole layer M0 with a metal having a lower resistivity.

### SUMMARY

The present disclosure aims to overcome the defects in the prior art and provides a method for reducing FINFET parasitic resistance. In this method, the strip-shaped contact hole M0 of the FinFET device is prepared by using carbon nanotube (CNT) as a conductive material, that is, the excellent conductive characteristics of the carbon nanotube are utilized to achieve the purpose of reducing the parasitic resistance of the FinFET devices

In order to achieve the purpose, the technical scheme of the invention is as follows:

A device structure for reducing FinFET parasitic resistance, comprising:
a FinFET silicon fin, a gate stack composed of a gate electrode and a gate dielectric layer, a strip-shaped contact hole layer M0 used for connecting out the source-drain region and a metal layer M1 used for the back-end process; wherein
the gate stack wraps the FinFET silicon fin from the two side and the surface respectively to form a three-dimensional channel of the FinFET device, and the lower end of the strip-shaped contact hole layer M0 covers and connects to the source-drain region of the FinFET device, and the upper end of the strip-shaped contact hole layer M0 connects to the metal layer M1 for realizing the connecting-out of the source-drain region of the FinFET device; wherein the material of the strip-shaped contact hole layer M0 is a single-wall carbon nanotube or multi-wall carbon nanotube.

Preferably, the FinFET silicon fin is isolated by shallow trench isolation (STI) medium.

Preferably, the gate stack is composed of a metal gate electrode and a high-k gate dielectric.

Preferably, the metal layer M1 is a copper interconnecting wire.

In order to achieve the aim, the invention further provides a technical scheme as follows: A manufacturing method of the device structure for reducing FinFET parasitic resistance, comprising:

Step S1: preparing a FinFET device like conventional FinFET structure, including preparing a FinFET silicon fin, forming a gate stack consisting of a gate electrode and a gate dielectric layer, and defining a source-drain region of the FinFET device; wherein the gate stack, which formed by the metal gate electrode and the gate dielectric layer in the FinFET device, wraps the FinFET silicon fin from the two sides and the surface respectively, to form a three-dimensional channel of the MOSFET;

Step S2: preparing a catalyst layer in the source-drain region;

Step S3: growing a carbon nanotube, to form a strip-shaped contact hole layer M0; wherein, the lower end of the strip-shaped contact hole layer M0 covers and is connected to the source-drain region of the FinFET device; the carbon nanotube is made of a single-wall carbon nanotube material or a multi-wall carbon nanotube material;

Step S4: achieving the source-drain region connected-out and carrying out the back-end process for preparation of the FinFET device, wherein the upper end of the strip-shaped contact hole layer M0 is connected to the metal layer M1.

Preferably, the process of preparing the FinFET device like conventional FinFET structure in the Step S1 comprises a combination of photoetching, etching, oxidation, deposition and/or epitaxial sub steps.

Preferably, the step S2 specifically comprises the following steps:

Step S21: defining the strip-shaped contact hole layer M0 through a photoetching and an etching process;

Step S22: depositing a catalyst layer in the strip-shaped contact hole layer M0 and the surface of the strip-shaped contact hole layer M0 by using an atomic layer deposition technology;

Step S23: enabling the catalyst layer to be granulated by an annealing process.

Preferably, the material of the catalyst layer is Fe, Co or Ni.

Preferably, the process of growing the carbon nanotube in the Step S3 is a chemical vapor deposition process.

Preferably, the process of achieving the source-drain region connected-out and the back-end process for preparation of the FinFET device in the step S4 is a traditional CMOS back-end process.

As can be seen from the technical scheme, the device structure of reducing FINFET parasitic resistance proposed by the present disclosure, which uses carbon nanotube as conductive material to fill the strip-shaped contact hole layer M0 of the FinFET, can obtain the following beneficial effects:

\textcircled{1}, due to the excellent electrical conductivity of the carbon nanotube, the current density of the carbon nanotube can be borne is 2-3 orders of magnitude higher than that of the current mainstream copper wire, the carbon nanotube is an ideal metal interconnecting material. Therefore, the parasitic resistance of the FINFET device can be greatly reduced.

\textcircled{2}, as a metal interconnection material, the carbon nanotube can be implemented in a traditional CMOS (Complementary Metal Oxide Semiconductor) back-end process. Therefore, the method of reducing FinFET parasitic resistance proposed by the present disclosure is not only easy to implement, but also maintains good process compatibility with the traditional CMOS process, and has very important application value.

### BRIEF DESCRIPTION OF THE DRAWINGS

FIG. 1 shows a typical schematic diagram of a FinFET device structure in the prior art

FIG. 2 shows a typical schematic diagram of a parasitic resistance of a FinFET device in the prior art

FIG. 3 shows a simulation result of the parasitic resistance of the FinFET device at each process node

FIG. 4 shows a schematic diagram of a device structure for reducing FinFET parasitic resistance according to an embodiment of the present disclosure

FIG. 5 is a flow chart of a manufacturing method of the device structure for reducing FinFET parasitic resistance according to an embodiment of the present disclosure

FIG. 6 is a schematic diagram of a semi-finished product obtained after the step S1 by adopting a manufacturing method of the device structure for reducing FinFET parasitic resistance in an embodiment of the present disclosure

FIG. 7 is a schematic diagram of a semi-finished product obtained after the step S2 by adopting a manufacturing method of the device structure for reducing FinFET parasitic resistance in an embodiment of the present disclosure

FIG. 8 is a schematic diagram of a semi-finished product obtained after the step S3 by adopting a manufacturing method of the device structure for reducing FinFET parasitic resistance in an embodiment of the present disclosure.

FIG. 9 is a schematic diagram of a finished product obtained after the step S4 by adopting a manufacturing method of the device structure for reducing FinFET parasitic resistance in an embodiment of the present disclosure

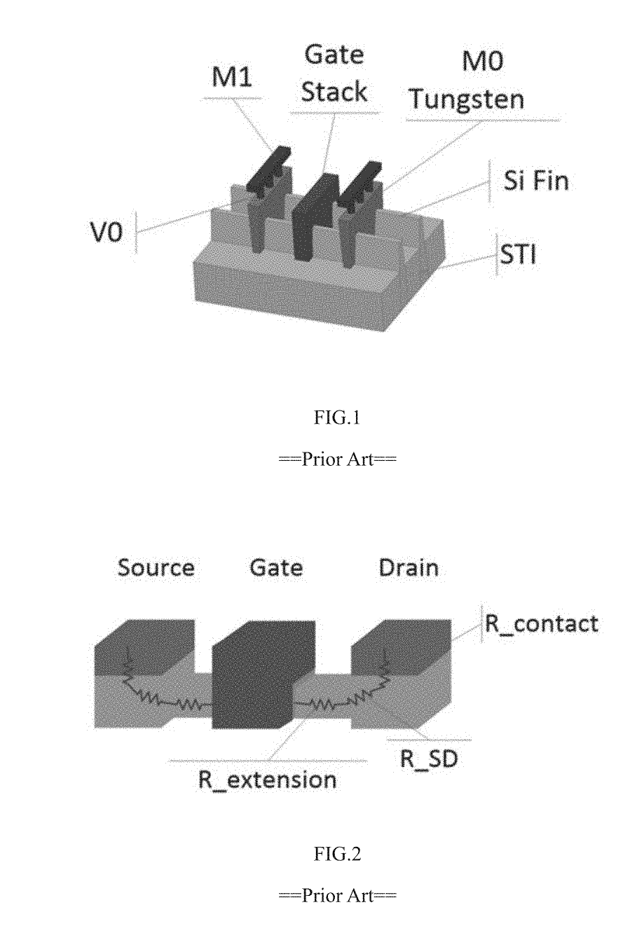

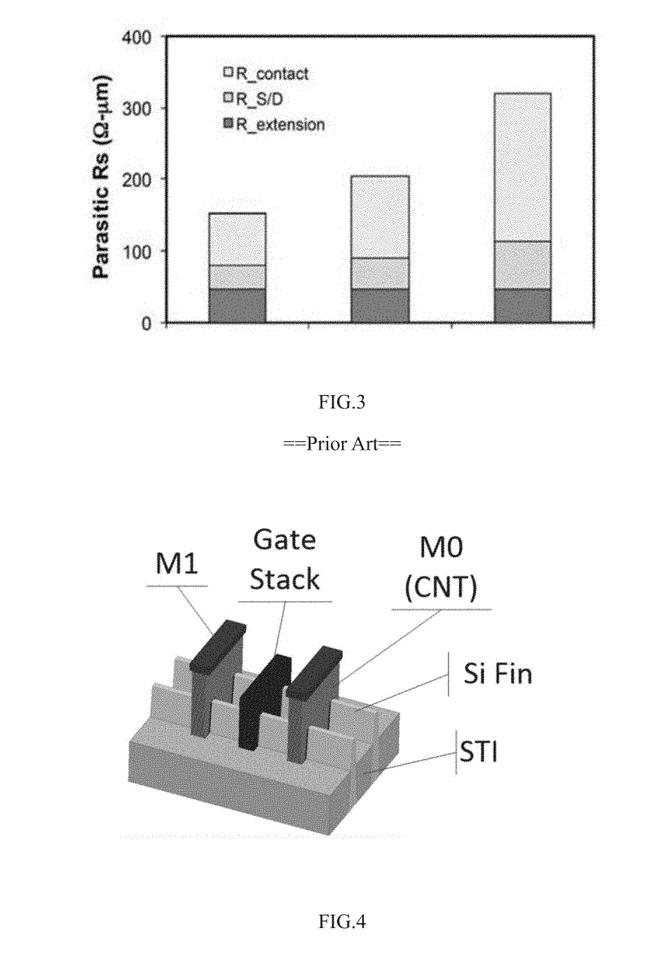

### DETAILED DESCRIPTION

Detailed description of specific embodiments of the present disclosure is described below with reference to the accompanying drawings. The present disclosure can have various changes in different examples, is not separated from the scope of the present disclosure, and the description and illustration thereof are regarded as illustrative in nature and not intended to limit the present disclosure.

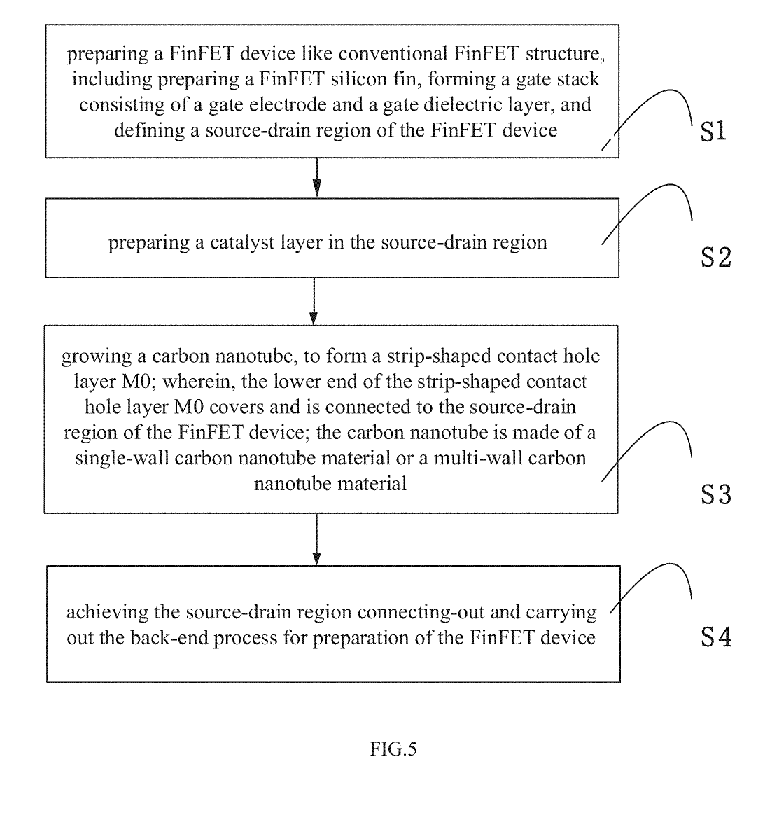

Refer to FIG. 4, FIG. 4. shows a schematic diagram of a device structure for reducing FinFET parasitic resistance according to an embodiment of the present disclosure. As shown, in the embodiment of the present disclosure, the device structure for reducing the FinFET parasitic resistance includes: a FinFET silicon fin (Si Fin), a gate stack composed of a gate electrode and a gate dielectric layer, a strip-shaped contact hole layer M0 used for connecting out the source-drain region and a metal layer M1 used for the back-end process. Wherein the gate stack wraps the FinFET silicon fin from the two sides and the surface respectively, to form a three-dimensional channel of the FinFET device, and the lower end of the strip-shaped contact hole layer M0 covers and connects to the source-drain region of the FinFET device, and the upper end of the strip-shaped contact hole layer M0 connects to the metal layer M1 for realizing the connecting-out of the source-drain region of the FinFET device.

In embodiments of the present disclosure, the strip-shaped contact hole layer M0 can be made of a single-wall or a multi-wall carbon nanotube material. In other words, the carbon nanotube (CNT) is adopted as conductive materials to prepare the strip-shaped contact hole M0 of the FinFET device, namely the carbon nanotube is used for replacing the metal tungsten contact hole in the prior art, so that the excellent conductive property of the carbon nanotube serving as an one-dimensional ideal wire is fully exerted, the purpose of reducing the parasitic resistance of the FINFET device is achieved.

As shown in FIG. 4, the FinFET silicon fin, the gate stack and the metal layer M1 can adopt a device structure and a material in the current mainstream FinFET technology, for example, the FinFET silicon fin usually be isolated by a shallow trench isolation (STI), and the gate stack is usually composed of a metal gate electrode and a high-k gate dielectric, the metal layer M1 can generally be a copper interconnecting wire.

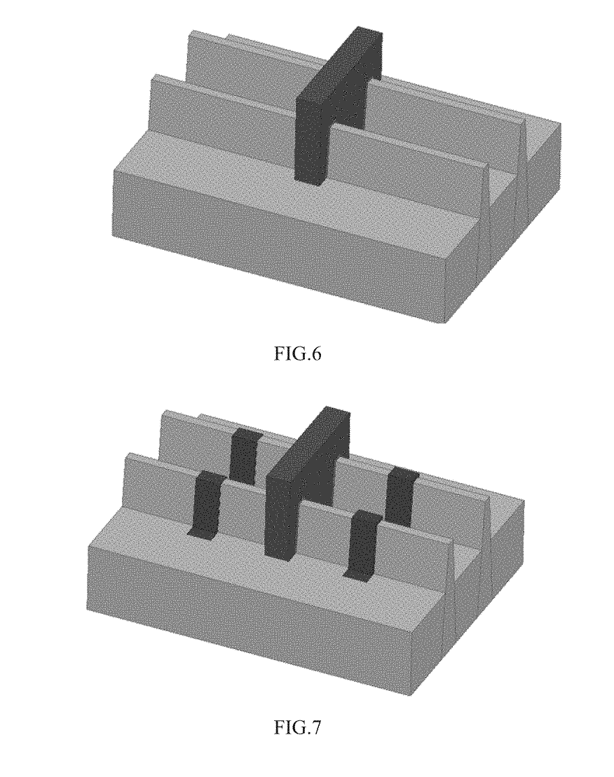

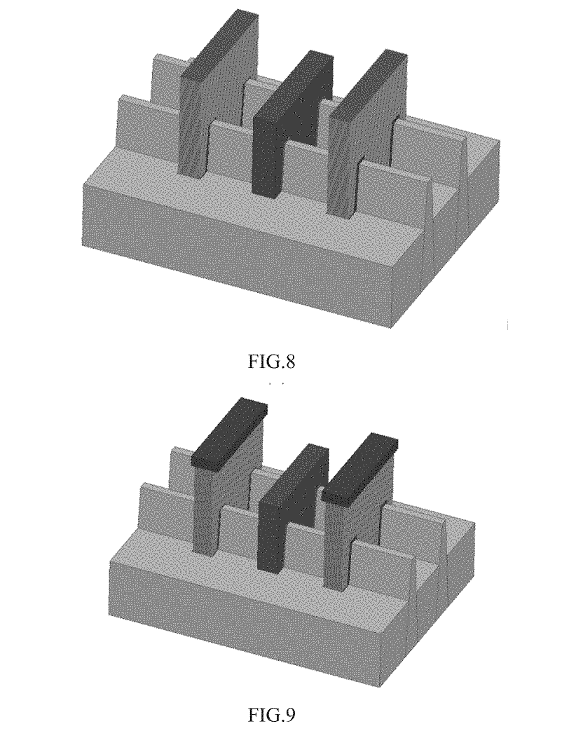

Next, please refer to FIG. 5, FIG. 5 is a flow chart of a method for manufacturing the device structure for reducing FINFET parasitic resistance according to an embodiment of the present disclosure. It should be noted that FIG. 9 and FIG. 4 are the same diagrams, and please refer to FIG. 5, FIG. 6, FIG. 7, FIG. 8 and FIG. 9 in combination with the marking text in FIG. 4. As shown in FIG. 5, the manufacturing method of the device structure for reducing FinFET parasitic resistance comprises the following steps:

Step S1: preparing a FinFET device like conventional FinFET structure, including preparing a FinFET silicon fin, forming a gate stack consisting of a gate electrode and a gate dielectric layer, and defining a source-drain region of the FinFET device; wherein the gate stack, which formed by the gate electrode and the gate dielectric layer in the FinFET device, wraps the FinFET silicon fin from the two sides and the surface respectively, to form a three-dimensional channel of the MOSFET.

Specifically, in embodiments of the present disclosure, the preparation process of the conventional FinFET device structure can adopt the existing mainstream FinFET technology, for example, a combination of technological process steps such as a series of photoetching, etching, oxidation, deposition, epitaxy and the like is included.

The above process and details are well known to skill technician in the art and are not described in detail here. The schematic diagram of the structure of conventional FinFET devices is shown in FIG. 6. It should be noted that various isolation dielectric materials can cover around the gate electrode and device structure surface in general. Here, for convenience of illustration, the various isolation dielectric materials are omitted (hereinafter referred to as the same).

Step S2: preparing a catalyst layer in a source-drain region; specifically, the step S2 comprises the following steps:

Step S21: defining the strip-shaped contact hole layer M0 through a photoetching and an etching process.

Step S22: depositing a catalyst layer in the strip-shaped contact hole layer M0 and the surface of the strip-shaped contact hole layer M0 using atomic layer deposition technology; wherein the material of the catalyst layer can be Fe, Co or Ni and the like, which are commonly used as a catalyst material for the growth of the carbon nanotube.

Step S23, enabling the catalyst layer to be granulated by an annealing process.

Referring to FIG. 7, FIG. 7 is a schematic diagram of a semi-finished product obtained after the step S2 by adopting a manufacturing method of the device structure for reducing FinFET parasitic resistance in an embodiment of the present disclosure. That is, the strip-shaped contact hole layer M0 is formed after completion of the step S2.

Step S3, growing a carbon nanotube, to form a strip-shaped contact hole layer M0; wherein, the lower end of the strip-shaped contact hole layer M0 covers and connects to the source-drain region of the FinFET device; the material of the strip-shaped contact hole layer M0 is a single-wall carbon nanotube or multi-wall carbon nanotube.

Specifically, please refer to FIG. 8, FIG. 8 is a schematic diagram of a semi-finished product obtained after the step S3 by adopting a manufacturing method of the device structure for reducing FinFET parasitic resistance in an embodiment of the present disclosure. That is, the carbon nanotube is grown after completion of the step S3.

The growth method of the carbon nanotubes is usually implemented by a chemical vapor deposition (CVD), wherein the material of the carbon nanotube can be a single-wall carbon nanotube material or a multi-wall carbon nanotube according to the specific growth process conditions.

Step S4, achieving the source-drain region connected-out and carrying out the back-end process for preparation of the FinFET device, wherein the upper end of the strip-shaped contact hole layer M0 is connected to the metal layer M1.

Specifically, the traditional CMOS (Complementary Metal Oxide Semiconductor) back-end process is adopted as the preparation process and are not described in detail here. Please refer to FIG. 9, FIG. 9 is a schematic diagram of a finished product obtained after the step S4 by adopting a manufacturing method of the device structure for reducing FinFET parasitic resistance in an embodiment of the present disclosure.

In conclusion, the method of reducing FinFET parasitic resistance proposed in the present disclosure adopts the carbon nanotube as the filler material of the strip-shaped contact hole layer M0 to replace the tungsten in the traditional FinFET device structure, so that the advantages of the carbon nanotubes as an ideal one-dimensional wire is fully exerted, and the purpose of reducing the parasitic resistance of the FinFET is achieved.

Meanwhile, as a metal interconnection material, the carbon nanotube can already be prepared in the traditional CMOS back-end process, so the method for reducing FinFET parasitic resistance proposed in the present disclosure is not only easy to implement, but also maintains good process compatibility with the traditional CMOS process, which has very important application value.

The above descriptions are only embodiments of the present disclosure, and the embodiments are not intended to limit the scope of the present disclosure, therefore, the equivalent structure changes which are made by applying the specification and the drawings of the present disclosure are applied, in the protection scope of the present disclosure.

What is claimed is:

1. A device structure for reducing FinFET parasitic resistance, comprising:
a FinFET silicon fin, a gate stack composed of a gate electrode and a gate dielectric layer, a strip-shaped contact hole layer M0 used for connecting-out the source-drain region and a metal layer M1 used for the back-end process; wherein
the gate stack wraps the FinFET silicon fin from the two sides and the surface respectively to form a three-dimensional channel of the FinFET device, and the lower end of the strip-shaped contact hole layer M0 covers and connects to the source-drain region of the FinFET device, and the upper end of the strip-shaped contact hole layer M0 connects to the metal layer M1 for realizing the connecting-out of the source-drain region of the FinFET device; wherein the material of the strip-shaped contact hole layer M0 is a single-wall carbon nanotube or multi-wall carbon nanotube.

2. The device structure of claim 1, wherein the FinFET silicon fin is isolated by shallow trench isolation.

3. The device structure of claim 1, wherein the gate stack is composed of a metal gate electrode and a high-k gate dielectric.

4. The device structure of claim 1, wherein the metal layer M1 is a copper interconnecting wire.

5. A manufacturing method of the device structure for reducing FinFET parasitic resistance, comprising:
Step S1: preparing a FinFET device like conventional FinFET structure, including preparing a FinFET silicon fin, forming a gate stack consisting of a gate electrode and a gate dielectric layer, and defining a source-drain region of the FinFET device; wherein the gate stack, which formed by the gate electrode and the gate dielectric layer in the FinFET device, wraps the FinFET silicon fin from the two sides and the surface respectively, to form a three-dimensional channel of the MOSFET;
Step S2: preparing a catalyst layer in the source-drain region;
Step S3: growing a carbon nanotube, to form a strip-shaped contact hole layer M0; wherein, the lower end of the strip-shaped contact hole layer M0 covers and connects to the source-drain region of the FinFET device; the carbon nanotube is made of a single-wall carbon nanotube material or a multi-wall carbon nanotube material;
Step S4: achieving the source-drain region connecting-out and carrying out the back-end process for preparation of the FinFET device, wherein the upper end of the strip-shaped contact hole layer M0 is connected to the metal layer M1.

6. The manufacturing method of claim 5, wherein the preparing the FinFET device like conventional FinFET structure in the Step S comprises a combination of photoetching, etching, oxidation, deposition and/or epitaxial sub steps.

7. The manufacturing method of claim 5, wherein the step S2 specifically comprises the following steps:
Step S21: defining the strip-shaped contact hole layer M0 through a photoetching and an etching process;
Step S22: depositing a catalyst layer in the strip-shaped contact hole layer M0 and the surface of the strip-shaped contact hole layer M0 using atomic layer deposition technology;
Step S23: enabling the catalyst layer to be granulated by an annealing process.

8. The method of claim 5, wherein the material of the catalyst is Fe, Co or Ni.

9. The manufacturing method of claim 5, wherein the growing the carbon nanotube in the Step S3 is adopting a chemical vapor deposition process.

10. The manufacturing method of claim 5, wherein the achieving the source-drain region connecting-out and the back-end process for preparation of the FinFET device in the step S4 is adopting a traditional CMOS back-end preparation process.
